(19) United States
(12) Patent Application Publication
(10) Pub. No.: US 2026/0362934 A1
(43) Pub. Date: Nov. 12, 2026

(54) DISPLAY PANEL AND ELECTRONIC DEVICE INCLUDING THE SAME

(71) Applicant: Samsung Display Co., LTD., Yongin-si (KR)

(72) Inventors: SUJUNG HUH, Yongin-si (KR); KOICHI ABE, Yongin-si (KR); WONJU KIM, Yongin-si (KR)

(21) Appl. No.: 19/392,521

(22) Filed: Nov. 18, 2025

(30) Foreign Application Priority Data
Mar. 7, 2025 (KR) 10-2025-0029424

(51) Int. Cl. H10K 59/50; H10H 29/80; H10H 29/851; H10H 29/856; H10K 59/38; H10K 59/80; H10K 102/00

(52) U.S. Cl. CPC H10K 59/50; H10H 29/8512; H10H 29/856; H10H 29/882; H10K 59/38; H10K 59/877; H10K 59/878; H10K 2102/331

(57) ABSTRACT

A display panel includes a first light-emitting layer emitting first light of a first wavelength, and a second light-emitting layer overlapping the first light-emitting layer and emitting second light of a longer second wavelength, a quantum dot layer, a color filter layer, and an optical anisotropic film layer. The quantum dot layer includes a first color conversion converting at least part of the first and second light into third light, and a second color conversion unit converting part of the first light into the second light, where the third light has a longer wavelength than the second light. The color filter layer includes red, green, and blue light filter units, each transmitting the corresponding light and positioned relative to the color conversion units. The optical anisotropic film layer between the quantum dot and color filter layers includes blue-green, blue, and green light reflective units to reflect respective light components.

This application claims priority to Korean Patent Application No. 10-2025-0029424, filed on Mar. 7, 2025, and all the benefits accruing therefrom under 35 U.S.C. § 119, the content of which in its entirety is herein incorporated by reference.

### BACKGROUND

### 1. Field

The present disclosure relates to a display panel and an electronic device including the display panel. More particularly, the present disclosure relates to a display panel having improved color conversion efficiency and an electronic device including such a display panel.

### 2. Description of the Related Art

A quantum dot display panel refers to a display panel that provides images using quantum dots. A quantum dot is a material whose energy band gap can be controlled according to its size and is capable of absorbing light having energy greater than its own energy band gap and emitting light with energy corresponding to its own energy band gap. That is, a quantum dot can convert the color (wavelength) of incident light to emit light having a different color (wavelength) from that of the incident light.

### SUMMARY

In order to improve the color conversion efficiency of a quantum dot display panel, the thickness of the quantum dot layer that includes quantum dots may be desired to be increased so that a greater amount of light is incident on the quantum dots. However, increasing the thickness of the quantum dot layer leads to an increase in the material costs to form the quantum dot layer.

The present disclosure provides a display panel and an electronic device including the display panel, in which an optical anisotropic film which reflects light of specific wavelengths is disposed between a quantum dot layer and a color filter layer, thereby improving color conversion efficiency without increasing the thickness of the quantum dot layer.

According to an embodiment of the present disclosure, a display panel includes a first light-emitting layer, a second light-emitting layer, a quantum dot layer, a color filter layer, and an optical anisotropic film layer. The first light-emitting layer emits first light having a first wavelength. The second light-emitting layer overlaps the first light-emitting layer and emits second light having a second wavelength longer than the first wavelength. The quantum dot layer includes a first color conversion unit and a second color conversion unit. The first color conversion unit converts at least part of the first light and the second light into third light. The second color conversion unit converts at least part of the first light into the second light. The third light has a third wavelength longer than the second wavelength.

In such an embodiment, the color filter layer includes a red light filter unit, a green light filter unit, and a blue light filter unit. The red light filter unit overlaps the first color conversion unit and transmits the third light. The green light filter unit overlaps the second color conversion unit and transmits the second light. The blue light filter unit is disposed not to overlap the first color conversion unit and the second color conversion unit, and transmits the first light.

In such an embodiment, the optical anisotropic film layer is disposed between the quantum dot layer and the color filter layer. The optical anisotropic film layer includes a blue-green light reflective unit, a blue light reflective unit, and a green light reflective unit. The blue-green light reflective unit overlaps the red light filter unit and reflects the second light and the third light. The blue light reflective unit overlaps the green light filter unit and reflects the first light. The green light reflective unit overlaps the blue light filter unit and reflects the second light.

In an embodiment, the blue-green light reflective unit may include a plurality of first liquid crystal molecules and a plurality of second liquid crystal molecules. The plurality of first liquid crystal molecules may be arranged in a helical structure having a first pitch. The plurality of second liquid crystal molecules may be arranged in a helical structure having a second pitch different from the first pitch. The blue light reflective unit may include a plurality of third liquid crystal molecules, which may be arranged in a helical structure having a third pitch substantially equal to the first pitch. The green light reflective unit may include a plurality of fourth liquid crystal molecules, which may be arranged in a helical structure having a fourth pitch substantially equal to the second pitch.

In an embodiment, two among a first liquid crystal molecule from the plurality of first liquid crystal molecules, a second liquid crystal molecule from the plurality of second liquid crystal molecules, a third liquid crystal molecule from the plurality of third liquid crystal molecules, and a fourth liquid crystal molecule from the plurality of fourth liquid crystal molecules may be different molecules.

In an embodiment, two among the concentration per unit volume of the plurality of first liquid crystal molecules, the concentration per unit volume of the plurality of second liquid crystal molecules, the concentration per unit volume of the plurality of third liquid crystal molecules, and the concentration per unit volume of the plurality of fourth liquid crystal molecules may be different from each other.

In an embodiment, at least selected from of the blue-green light reflective unit, the blue light reflective unit, and the green light reflective unit may further include a plurality of chiral dopants.

In an embodiment, some of the plurality of first liquid crystal molecules may be arranged in helical structures having a first rotational direction, and a remainder of the plurality of first liquid crystal molecules may be arranged in helical structures having a second rotational direction. Some of the plurality of second liquid crystal molecules may be arranged in helical structures having the first rotational direction, and a remainder of the plurality of second liquid crystal molecules may be arranged in helical structures having the second rotational direction. Some of the plurality of third liquid crystal molecules may be arranged in helical structures having the first rotational direction, and a remainder of the plurality of third liquid crystal molecules may be arranged in helical structures having the second rotational direction. Some of the plurality of fourth liquid crystal molecules may be arranged in helical structures having the first rotational direction, and a remainder of the plurality of fourth liquid crystal molecules may be arranged in helical structures having the second rotational direction. The first rotational direction may be different from the second rotational direction.

In an embodiment, the optical anisotropic film layer of the display panel may further include a scattering unit which scatters incident light.

In an embodiment, the scattering unit may be disposed between two adjacent units of the blue-green light reflective unit, the blue light reflective unit, and the green light reflective unit.

In an embodiment, the plurality of first liquid crystal molecules may be disposed above or below the plurality of second liquid crystal molecules.

In an embodiment, the scattering unit may include a plurality of fifth liquid crystal molecules. Each of the plurality of first liquid crystal molecules, the plurality of second liquid crystal molecules, the plurality of third liquid crystal molecules, and the plurality of fourth liquid crystal molecules may be arranged in a helical structure in a planar state or a homeotropic state. The plurality of fifth liquid crystal molecules may be arranged in a helical structure in a focal conic state.

In another embodiment of the disclosure, a display panel includes a first light-emitting layer, a second light-emitting layer, a quantum dot layer and a color filter layer, a blue-green light reflective unit, a blue light reflective unit, and a green light reflective unit. The first light-emitting layer emits first light having a first wavelength. The second light-emitting layer emits second light having a second wavelength longer than the first wavelength. The second light-emitting layer overlaps the first light-emitting layer.

In such an embodiment, the quantum dot layer includes a first color conversion unit and a second color conversion unit. The first color conversion unit converts at least part of the first light and the second light into third light. The second color conversion unit converts at least part of the first light into the second light. The third light may have a third wavelength longer than the second wavelength.

In such an embodiment, the color filter layer may include a color filter layer that includes a red light filter unit which transmits the third light, a green light filter unit which transmits the second light, and a blue light filter unit which transmits the first light.

In such an embodiment, the blue-green light reflective unit includes a plurality of first liquid crystal molecules and a plurality of second liquid crystal molecules. The plurality of first liquid crystal molecules is arranged in a helical structure having a first pitch between the first color conversion unit and the red light filter unit. The plurality of second liquid crystal molecules is arranged in a helical structure having a second pitch different from the first pitch between the first color conversion unit and the red light filter unit.

In such an embodiment, the blue light reflective unit includes a plurality of third liquid crystal molecules arranged in a helical structure having a third pitch substantially equal to the first pitch between the second color conversion unit and the green light filter unit. the green light reflective unit overlaps the blue light filter unit and includes a plurality of fourth liquid crystal molecules arranged in a helical structure having a fourth pitch substantially equal to the second pitch.

In an embodiment, two among a first liquid crystal molecule from the plurality of first liquid crystal molecules, a second liquid crystal molecule from the plurality of second liquid crystal molecules, a third liquid crystal molecule from the plurality of third liquid crystal molecules, and a fourth liquid crystal molecule from the plurality of fourth liquid crystal molecules may be different molecules.

In an embodiment, two among the concentration per unit volume of the plurality of first liquid crystal molecules, the concentration per unit volume of the plurality of second liquid crystal molecules, the concentration per unit volume of the plurality of third liquid crystal molecules, and the concentration per unit volume of the plurality of fourth liquid crystal molecules may be different from each other.

In an embodiment, at least one selected from the blue-green light reflective unit, the blue light reflective unit, and the green light reflective unit may further include a plurality of chiral dopants.

In an embodiment, some of the plurality of first liquid crystal molecules may be arranged in helical structures having a first rotational direction, and the remainder may be arranged in helical structures having a second rotational direction. Some of the plurality of second liquid crystal molecules may be arranged in helical structures having the first rotational direction, and a remainder of the plurality of second liquid crystal molecules may be arranged in helical structures having the second rotational direction. Some of the plurality of third liquid crystal molecules may be arranged in helical structures having the first rotational direction, and a remainder of the plurality of third liquid crystal molecules may be arranged in helical structures having the second rotational direction. Some of the plurality of fourth liquid crystal molecules may be arranged in helical structures having the first rotational direction, and a remainder of the plurality of fourth liquid crystal molecules may be arranged in helical structures having the second rotational direction. The first rotational direction and the second rotational direction may be different from each other.

In an embodiment, the display panel may further include a scattering unit which scatters incident light and is disposed between the quantum dot layer and the color filter layer.

In an embodiment, the scattering unit may include a plurality of fifth liquid crystal molecules. Each of the plurality of first liquid crystal molecules, the plurality of second liquid crystal molecules, the plurality of third liquid crystal molecules, and the plurality of fourth liquid crystal molecules may be arranged in a helical structure in a planar state or in a homeotropic state. The plurality of fifth liquid crystal molecules may be arranged in a helical structure in a focal conic state.

In an embodiment, the plurality of first liquid crystal molecules may be disposed above or below the plurality of second liquid crystal molecules.

In an embodiment of the present disclosure, an electronic device includes a display panel, a processor, a memory, and a power module. The display panel emits light. The processor controls the display panel. The memory stores data including instructions for operating at least one selected from the display panel and the processor. The power module generates power.

In such an embodiment, the display panel includes a first light-emitting layer, a second light-emitting layer, a quantum dot layer, a color filter layer, and an optical anisotropic film layer. The first light-emitting layer emits first light having a first wavelength. The second light-emitting layer overlaps the first light-emitting layer and emits second light having a second wavelength longer than the first wavelength.

In such an embodiment, the quantum dot layer includes a first color conversion unit and a second color conversion unit. The first color conversion unit converts at least part of the first light and the second light into third light. The second color conversion unit converts at least part of the first light into the second light. The third light may have a third wavelength longer than the second wavelength.

In such an embodiment, the color filter layer includes a red light filter unit, a green light filter unit, and a blue light filter unit. The red light filter unit overlaps the first color conversion unit and transmits the third light. The green light filter unit overlaps the second color conversion unit and transmits the second light. The blue light filter unit is disposed not to overlap the first color conversion unit and the second color conversion unit and transmits the first light.

In such an embodiment, the optical anisotropic film layer is disposed between the quantum dot layer and the color filter layer. The optical anisotropic film layer includes a blue-green light reflective unit, a blue light reflective unit, and a green light reflective unit. The blue-green light reflective unit overlaps the first color conversion unit and reflects the second light and the third light. The blue light reflective unit overlaps the second color conversion unit and reflects the first light. The green light reflective unit is disposed not to overlap the first color conversion unit and the second color conversion unit and reflects the second light.

In an embodiment, the blue-green light reflective unit may include a plurality of first liquid crystal molecules and a plurality of second liquid crystal molecules. The plurality of first liquid crystal molecules may be arranged in a helical structure having a first pitch. The plurality of second liquid crystal molecules may be arranged in a helical structure having a second pitch different from the first pitch. The blue light reflective unit may include a plurality of third liquid crystal molecules arranged in a helical structure having a third pitch substantially equal to the first pitch. The green light reflective unit may include a plurality of fourth liquid crystal molecules arranged in a helical structure having a fourth pitch substantially equal to the second pitch.

In embodiments of a display panel and an electronic device including the display panel according to the present disclosure, an optical anisotropic film which reflects light of specific wavelengths is disposed between a quantum dot layer and a color filter layer, thereby enabling improvement in color conversion efficiency without increasing the thickness of the quantum dot layer.

### BRIEF DESCRIPTION OF THE DRAWINGS

These and/or other features of embodiments of the present disclosure will become apparent and more readily appreciated from the following description of the embodiments thereof, taken in conjunction with the accompanying drawings, in which:

FIGS. 1A and 1B are a perspective view and an exploded perspective view, respectively, illustrating an electronic device according to an embodiment of the present disclosure;

FIG. 2 is a plan view illustrating a display panel shown in FIG. 1B;

FIG. 3A is a partial cross-sectional view illustrating a pixel shown in FIG. 2;

FIG. 3B illustrates emission of first light, second light, and third light from the pixel shown in FIG. 3A;

FIG. 4 illustrates the helical structure and pitch of liquid crystal molecules in an optical anisotropic film shown in FIG. 3A;

FIGS. 5A to 5C illustrate the selective reflection characteristics of reflective units shown in FIG. 3A;

FIG. 6 additionally illustrates the rotational direction of the helical structure shown in FIG. 4;

FIGS. 7A and 7B are graphs illustrating the relationship between the rotational direction of the helical structure and the reflectance of the blue light reflective unit;

FIG. 8A illustrates a partial cross-sectional view of a pixel according to another embodiment of the present disclosure;

FIG. 8B illustrates emission of first light, second light, and third light from the pixel shown in FIG. 8A;

FIG. 9A illustrates a partial cross-sectional view of a pixel according to another embodiment of the present disclosure;

FIG. 9B illustrates emission of first light, second light, and third light from the pixel shown in FIG. 9A;

FIG. 10A illustrates the helical structure and pitch of liquid crystal molecules in the optical anisotropic film shown in FIG. 9A;

FIG. 10B additionally illustrates the rotational direction of the helical structure shown in FIG. 10A;

FIG. 11 illustrates a partial cross-sectional view of a pixel according to another embodiment of the present disclosure;

FIG. 12A is a block diagram illustrating the electronic device shown in FIG. 1A; and

FIG. 12B illustrates various embodiments of the electronic device.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

When an element (or region, layer, portion, or the like) is described to be “disposed on,” “placed on,” “arranged on,” “connected to,” or “coupled to” another element, it shall be construed as being disposed on, placed on, arranged on, connected to, or coupled to the other element directly but also as possibly having another element therebetween. If one element is described to be “directly disposed on,” “directly placed on,” “directly arranged on,” “directly connected to,” or “directly coupled to” another element, it shall be construed that there is no other element interposed therebetween.

Like or identical reference numerals refer to like or identical elements. Moreover, in the accompanying drawings, the thicknesses, ratios, and dimensions of the elements may not be to exact scale and may have been exaggerated for the benefit of effective explanation of the technical features associated with these elements. As such, the present disclosure shall not be restricted to the thicknesses, ratios, dimensions, characteristics, and the like illustrated in the drawings.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

Moreover, relative terms, such as “below,” “under,” “beneath,” “lower,” “bottom,” “above,” “over,” “upper,” “top,” and the like may be used herein to describe one element's relationship to another element as illustrated in the accompanying figures. It shall be understood that relative terms are intended to encompass different orientations of the device in addition to the orientation depicted in the accompanying figures. For example, if the device in one of the figures is turned over, elements described as being on the “lower” side of the other elements would then be oriented on “upper” sides of the other elements. The example term “lower” can therefore encompass an orientation of both “lower” and “upper,” depending on the particular orientation of the figure. Similarly, if the device in one of the figures is turned over, elements described as “below” or “beneath” other elements would then be oriented “above” the other elements. The example term “below” or “beneath” can therefore encompass an orientation of both above and below.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

The term “substantially,” as used herein, means approximately or actually. The term “substantially equal” means approximately or actually equal. The term “substantially the same” means approximately or actually the same. The term “substantially perpendicular” means approximately or actually perpendicular. The term “substantially parallel” means approximately or actually parallel.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

In the present specification, if any embodiment can be differently implemented, the specified order of process may be performed differently than the described order. For example, two processes described to be performed sequentially may be performed simultaneously or performed in a reverse order.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

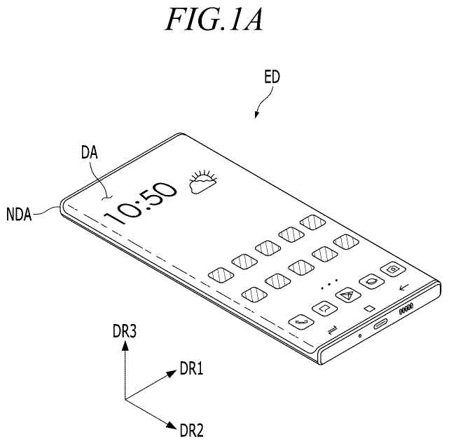

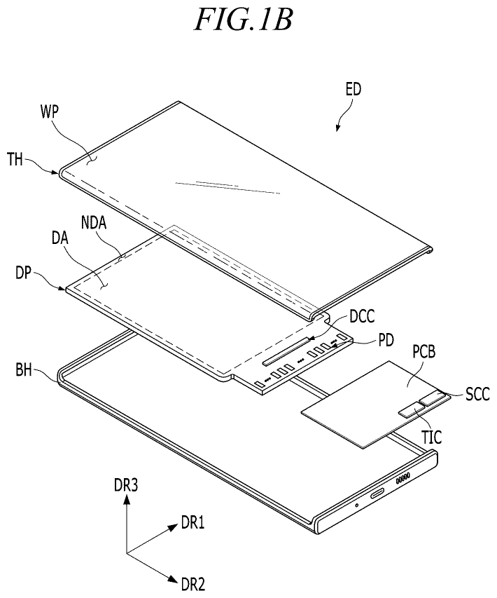

FIGS. 1A and 1B are a perspective view and an exploded perspective view, respectively, illustrating an electronic device ED according to an embodiment of the disclosure. Referring to FIGS. 1A and 1B, a display area DA and a non-display area NDA may be defined in an embodiment of the electronic device ED.

The display area DA may correspond to a region where an image is displayed. The display area DA may be parallel to a plane defined by a first direction DR1 and a second direction DR2. The second direction DR2 may intersect the first direction DR1. A third direction DR3 may be a normal direction to the display area DA, and may be a thickness direction of the electronic device ED.

The non-display area NDA may correspond to a region where no image is displayed and may surround the display area DA. However, the illustrated shapes of the display area DA and the non-display area NDA in FIGS. 1A and 1B are merely examples, and the actual shapes of the display area DA and the non-display area NDA may be variously modified as desired.

Referring to FIGS. 1A and 1B, an embodiment of the electronic device ED may include an upper housing TH, a lower housing BH, and a display panel DP.

The upper housing TH may include a window member WP and may be disposed above the display panel DP. The window member WP may allow incident light to transmit therethrough. In an embodiment, an image displayed on the display panel DP may be visible to the user through the window member WP. The window member WP may overlap the display area DA in the third direction DR3 and may include a transparent material capable of transmitting light. The window member WP may also include an insulating material. In an embodiment, for example, the window member WP may include at least one selected from glass and plastic.

The lower housing BH may be disposed below the display panel DP. The lower housing BH may be configured to protect the display panel DP from external impact and may accommodate the display panel DP.

The display panel DP may be configured to emit light. A display area DA and a non-display area NDA of the display panel DP may be defined to, respectively, overlap the display area DA and the non-display area NDA of the electronic device ED.

In an embodiment, for example, the display panel DP may be a self-emissive display panel. in an embodiment, for example, the display panel DP may be one of an organic light-emitting display panel, a quantum dot display panel, a micro light-emitting diode display panel, a liquid crystal display panel, an electrophoretic display panel, and an electrowetting display panel. A light-emitting layer of the organic light-emitting display panel may include an organic light-emitting material. An inorganic light-emitting display panel may include quantum dot display panels and micro light-emitting display panels based on inorganic materials.

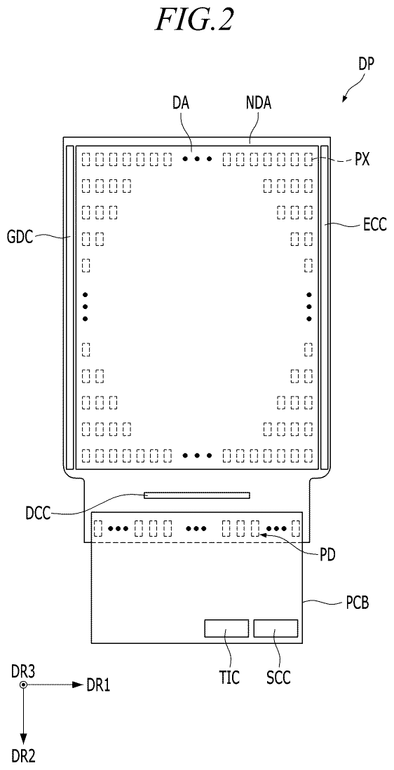

FIG. 2 is a plan view illustrating the display panel DP shown in FIG. 1B. Referring to FIGS. 1B and 2, the display panel DP may include a gate driver circuit GDC, a light-emission control circuit ECC, a data driver circuit DCC, a printed circuit board PCB, a input sensing driver circuit TIC, a signal control circuit SSC, a plurality of pads PD, and pixels PX.

The gate driver circuit GDC may be configured to receive a control signal from the signal control circuit SCC and to provide a gate signal to the pixels PX. The gate driver circuit GDC may be formed simultaneously with the pixels PX through a same thin-film process. In an embodiment, for example, the gate driver circuit GDC may be provided in the form of an oxide semiconductor TFT gate driver circuit (OSG) or an amorphous silicon TFT gate driver circuit (ASG).

The light-emission control circuit ECC may be configured to receive a control signal from the signal control circuit SCC and to provide a light-emission control signal to the pixels PX. The light-emission control signal may be an electrical signal for controlling light emission.

The data driver circuit DCC may be configured to receive a control signal from the signal control circuit SCC and to provide a data signal to the pixels PX.

The input sensing driver circuit TIC and the signal control circuit SSC may be mounted on the printed circuit board PCB and may be configured to receive electrical signals from the plurality of pads PD. The input sensing driver circuit TIC may be configured to process signals corresponding to a user's touch and signals corresponding to pressure applied from the outside.

The signal control circuit SSC (e.g., a timing controller) may be configured to control at least one selected from the input sensing driver circuit TIC, the gate driver circuit GDC, the data driver circuit DCC, and the light-emission control circuit ECC. The signal control circuit SCC may be configured to receive image data and control signals from an external graphics controller (not shown). The control signals may include a vertical sync signal, a horizontal sync signal, a data enable signal, and a clock signal. The vertical sync signal may be a signal for distinguishing frame intervals, and the horizontal sync signal may be a signal for distinguishing horizontal intervals (i.e., a row-selecting signal).

Although FIG. 2 illustrates an embodiment where the gate driver circuit GDC and the light-emission control circuit ECC are provided as separate components that are spaced apart from each other, the configuration of the gate driver circuit GDC and the light-emission control circuit ECC is not limited thereto. In another embodiment, for example, the gate driver circuit GDC and the light-emission control circuit ECC may be provided as a single component or circuit.

The pixels PX may be provided as a plurality of units.

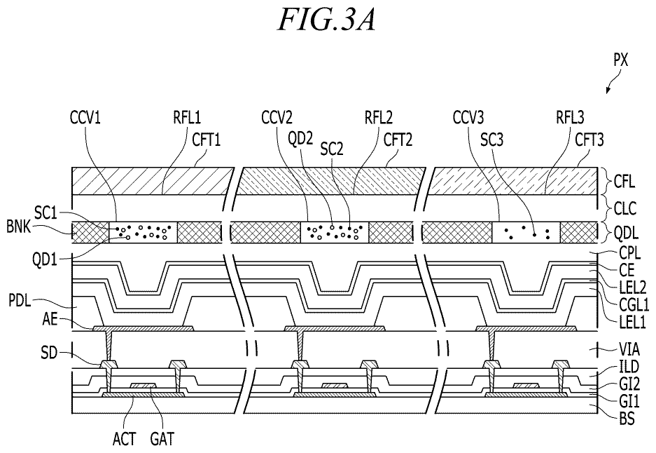

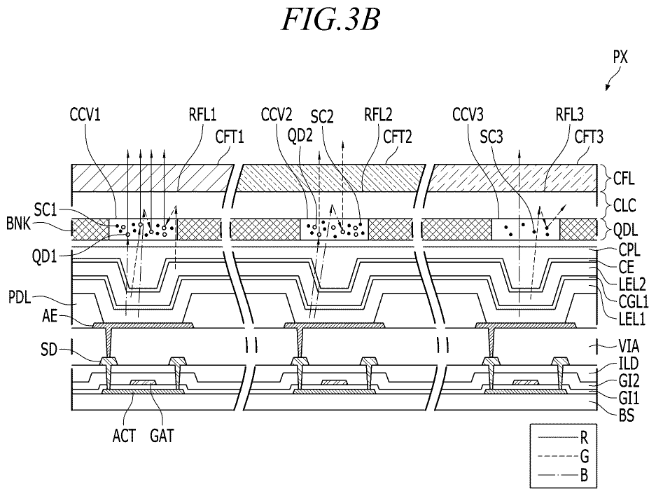

FIG. 3A is a partial cross-sectional view schematically illustrating a pixel PX shown in FIG. 2. FIG. 3B schematically illustrates emission of first light B, second light G, and third light R from the pixel PX shown in FIG. 3A.

Referring to FIG. 3A, in an embodiment, the pixel PX may include a base substrate BS, a semiconductor pattern ACT, gate insulating layers GI1, GI2, a gate pattern GAT, an interlayer insulating layer ILD, a conductive pattern SD, a via layer VIA, an anode electrode AE, a pixel defining layer PDL, a first light-emitting layer LEL1, a first charge generation layer CGL1, a second light-emitting layer LEL2, a cathode electrode CE, an encapsulation layer CPL, a quantum dot layer QDL, an optical anisotropic film layer CLC, and a color filter layer CFL.

The gate insulating layers GI1, GI2 may include a first gate insulating layer GI1 and a second gate insulating layer GI2.

The base substrate BS may include at least one selected from glass, metal, and polymer materials.

The semiconductor pattern ACT may be disposed on the base substrate BS and may include a semiconductor material. In an embodiment, for example, the semiconductor material may include at least one selected from an amorphous silicon semiconductor, a polycrystalline silicon semiconductor, a metal oxide semiconductor, a crystalline oxide semiconductor, and an amorphous oxide semiconductor. The oxide semiconductor may include at least one selected from indium-tin oxide (ITO), indium-gallium-zinc oxide (IGZO), zinc oxide (ZnO), indium-zinc oxide (IZnO), zinc-indium oxide (ZIO), indium oxide (InO), titanium oxide (TiO), indium-zinc-tin oxide (IZTO), and zinc-tin oxide (ZTO).

The first gate insulating layer GI1 may be disposed on the base substrate BS and may cover the semiconductor pattern ACT. The first gate insulating layer GI1 may include at least one selected from organic insulating materials and inorganic insulating materials. In an embodiment, for example, the first gate insulating layer GI1 may include at least one selected from polysiloxane, silicon nitride, silicon oxide, silicon oxynitride, polyacrylic compounds, polyimide compounds, fluorinated carbon compounds, and benzocyclobutene compounds. In another embodiment of the disclosure, the first gate insulating layer GI1 may be provided in plural.

The gate pattern GAT may be disposed on the first gate insulating layer GI1. At least a portion of the gate pattern GAT may overlap the semiconductor pattern ACT. The gate pattern GAT may include a metal. In an embodiment, for example, the gate pattern GAT may include at least one selected from gold (Au), silver (Ag), aluminum (Al), molybdenum (Mo), chromium (Cr), titanium (Ti), nickel (Ni), neodymium (Nd), and copper (Cu).

The second gate insulating layer GI2 may be disposed on the first gate insulating layer GI1 and may cover the gate pattern GAT. The second gate insulating layer GI2 may include at least one selected from organic insulating materials and inorganic insulating materials. In an embodiment, for example, the second gate insulating layer GI2 may include at least one selected from polysiloxane, silicon nitride, silicon oxide, silicon oxynitride, polyacrylic compounds, polyimide compounds, fluorinated carbon compounds, and benzocyclobutene compounds. In another embodiment of the disclosure, the second gate insulating layer GI2 may be provided in plural.

The interlayer insulating layer ILD may be disposed on the second gate insulating layer GI2 and may cover the second gate insulating layer GI2. The interlayer insulating layer ILD may include an insulating material. In an embodiment, for example, the interlayer insulating layer ILD may include at least one selected from polysiloxane, silicon nitride, silicon oxide, and silicon oxynitride.

The conductive pattern SD may be disposed on the interlayer insulating layer ILD and may be electrically connected to at least one selected from the semiconductor pattern ACT and the gate pattern GAT. The conductive pattern SD may include a metal. In an embodiment, for example, the conductive pattern SD may include at least one selected from gold (Au), silver (Ag), aluminum (Al), molybdenum (Mo), chromium (Cr), titanium (Ti), nickel (Ni), neodymium (Nd), and copper (Cu).

The via layer VIA may be disposed on the interlayer insulating layer ILD and may cover the conductive pattern SD.

The anode electrode AE may be electrically connected to at least one selected from the semiconductor pattern ACT and the gate pattern GAT through the conductive pattern SD.

The pixel defining layer PDL may be disposed on the via layer VIA. An opening at least partially exposing the anode electrode AE may be defined or formed through the pixel defining layer PDL.

Each of the first light-emitting layer LEL1 and the second light-emitting layer LEL2 may be disposed on the pixel defining layer PDL to cover the pixel defining PDL and an exposed portion of the anode electrode AE through the opening. Each of the first light-emitting layer LEL1 and the second light-emitting layer LEL2 may be configured to emit either first light B or second light G.

In an embodiment, the first light-emitting layer LEL1 may be configured to emit first light B. The first light B may be blue light and may have a first wavelength. In an embodiment, for example, the first wavelength may be greater than or equal to about 400 nanometers (nm) and smaller than or equal to about 480 nm.

The first charge generation layer CGL1 may be disposed between the first light-emitting layer LEL1 and the second light-emitting layer LEL2 and may cover the first light-emitting layer LEL1. The first charge generation layer CGL1 may include a conductive material.

In an embodiment of the present disclosure, the second light-emitting layer LEL2 may overlap the first light-emitting layer LEL1 and may be configured to emit second light G. The second light G may be green light and may have a second wavelength. The second wavelength may be longer than the first wavelength. In an embodiment, for example, the second wavelength may be greater than or equal to about 510 nm and smaller than or equal to about 550 nm.

The cathode electrode CE may be disposed above the first light-emitting layer LEL1 and the second light-emitting layer LEL2. While an electrical signal provided to the anode electrode AE is transmitted through the first light-emitting layer LEL1 and the second light-emitting layer LEL2 to the cathode electrode CE, the first light-emitting layer LEL1 and the second light-emitting layer LEL2 may emit light.

The encapsulation layer CPL may be disposed above the first light-emitting layer LEL1 and the second light-emitting layer LEL2 and may cover the cathode electrode CE. The encapsulation layer CPL may be configured to protect the first light-emitting layer LEL1 and the second light-emitting layer LEL2 from oxygen and moisture. In an embodiment, for example, the encapsulation layer CPL may include at least one selected from silicon oxide, silicon nitride, and silicon oxynitride. The encapsulation layer CPL may include at least one selected from organic and inorganic materials. In an embodiment, for example, the encapsulation layer CPL may further include at least one separate layer containing at least one selected from organic and inorganic materials.

The quantum dot layer QDL may be configured to absorb light emitted from the first light-emitting layer LEL1 and the second light-emitting layer LEL2 and to emit light having a wavelength different from that of the light emitted from the first light-emitting layer LEL1 and the second light-emitting layer LEL2.

A quantum dot is a material whose energy band gap can be adjusted according to its size. A quantum dot may absorb light having energy greater than its own energy band gap and emit light having energy corresponding to its energy band gap. That is, a quantum dot may absorb incident light and emit light having a wavelength different from that of the incident light.

Scattering materials SC1, SC2, SC3 may be configured to scatter incident light. That is, the scattering materials SC1, SC2, SC3 may alter the path of light without changing the wavelength of the light. In the quantum dot layer QDL, the scattering materials SC1, SC2, SC3 may function to scatter incident light toward the quantum dots.

The quantum dot layer QDL may include a bank BNK, a first color conversion unit CCV1, a second color conversion unit CCV2, and a third color conversion unit CCV3.

The bank BNK may be disposed on the encapsulation layer CPL and may overlap the pixel defining layer PDL. The bank BNK may be configured to block light emitted from the first light-emitting layer LEL1 and the second light-emitting layer LEL2. A plurality of openings may be defined in the bank BNK. The first color conversion unit CCV1, the second color conversion unit CCV2, and the third color conversion unit CCV3 may each be disposed in a corresponding one of the plurality of openings and may overlap the anode electrode AE. In another embodiment of the disclosure, the bank BNK may be omitted.

The first color conversion unit CCV1 may include a plurality of first quantum dots QD1 and a plurality of first scattering materials SC1.

The first quantum dots QD1 may be configured to convert each of the first light B and the second light G into third light R. The third light R may be red light and may have a third wavelength. The third wavelength may be longer than the second wavelength. In an embodiment, for example, the third wavelength may be greater than or equal to about 610 nm and smaller than or equal to about 650 nm.

The first scattering material SC1 may function such that each of the first light B and the second light G is scattered and incident on the first quantum dots QD1.

The second color conversion unit CCV2 may include a plurality of second quantum dots QD2 and a plurality of second scattering materials SC2. The second quantum dots QD2 may be configured to convert the first light B into the second light G, and the second scattering materials SC2 may function to scatter the first light B to be incident on the second quantum dots QD2.

The third color conversion unit CCV3 may include a plurality of third scattering materials SC3. The third scattering materials SC3 may be configured to scatter the second light G. In another embodiment of the present disclosure, the third color conversion unit CCV3 may be omitted.

The color filter layer CFL may be disposed above the optical anisotropic film layer CLC. The color filter layer CFL may include a red light filter unit CFT1, a green light filter unit CFT2, and a blue light filter unit CFT3.

The red light filter unit CFT1 may overlap the first color conversion unit CCV1 and may be configured to allow the third light R to transmit therethrough and block the first light B and the second light G.

The green light filter unit CFT2 may overlap the second color conversion unit CCV2 and may be configured to allow the second light G to transmit therethrough and block the first light B and the third light R.

The blue light filter unit CFT3 may overlap the third color conversion unit CCV3 and may be configured to allow the first light B to transmit therethrough and block the second light G and the third light R.

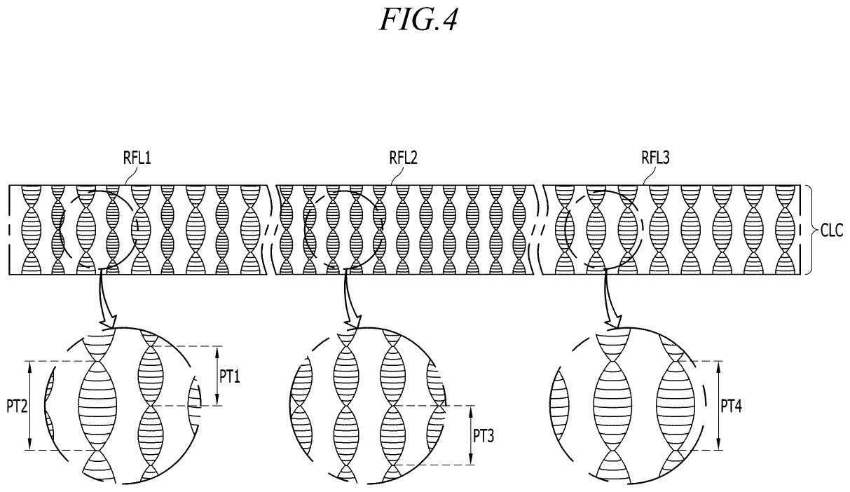

The optical anisotropic film layer CLC may be disposed between the quantum dot layer QDL and the color filter layer CFL. The optical anisotropic film layer CLC may include a blue-green light reflective unit RFL1, a blue light reflective unit RFL2, and a green light reflective unit RFL3 (shown in FIG. 4). In an embodiment, for example, the optical anisotropic film layer CLC may be a cholesteric liquid crystal.

The blue-green light reflective unit RFL1 may be disposed between the first color conversion unit CCV1 and the red light filter unit CFT1 and may overlap the red light filter unit CFT1. The blue-green light reflective unit RFL1 may be configured to reflect the first light B and the second light G. The blue-green light reflective unit RFL1 may improve the efficiency with which the first light B and the second light G are converted into the third light R.

Referring to FIG. 3B, the first light-emitting layer LEL1 and the second light-emitting layer LEL2 may be configured to emit first light B and second light G, respectively. A portion of the first light B emitted from the first light-emitting layer LEL1 may be converted into third light R by the first quantum dots QD1 and transmitted through the red light filter unit CFT1. Another portion of the first light B emitted from the first light-emitting layer LEL1 may pass through the first color conversion unit CCV1, be reflected by the blue-green light reflective unit RFL1, and then re-enter the first quantum dots QD1. The first light B reflected by the blue-green light reflective unit RFL1 may be converted into third light R by the first quantum dots QD1.

A portion of the second light G emitted from the second light-emitting layer LEL2 may be converted into third light R by the first quantum dots QD1 and transmitted through the red light filter unit CFT1. Another portion of the second light G emitted from the second light-emitting layer LEL2 may pass through the first color conversion unit CCV1, be reflected by the blue-green light reflective unit RFL1, and then re-enter the first quantum dots QD1. The second light G reflected by the blue-green light reflective unit RFL1 may be converted into third light R by the first quantum dots QD1.

In such an embodiment, the first light B and the second light G that are not converted into third light R by the first quantum dots QD1 may be reflected by the blue-green light reflective unit RFL1. The reflected first light B and second light G may then be incident on the first quantum dots QD1 and converted into third light R. Through the process described above, the efficiency with which the first light B and the second light G are converted into third light R may be improved.

The blue light reflective unit RFL2 may be disposed between the second color conversion unit CCV2 and the green light filter unit CFT2 and may overlap the green light filter unit CFT2. The blue light reflective unit RFL2 may be configured to reflect the first light B. The blue light reflective unit RFL2 may improve the efficiency with which the first light B is converted into second light G.

Referring to FIG. 3B, the first light-emitting layer LEL1 and the second light-emitting layer LEL2 may be configured to emit first light B and second light G, respectively. A portion of the first light B emitted from the first light-emitting layer LEL1 may be converted into second light G by the second quantum dots QD2 and transmitted through the green light filter unit CFT2. Another portion of the first light B emitted from the first light-emitting layer LEL1 may pass through the second color conversion unit CCV2, be reflected by the blue light reflective unit RFL2, and then re-enter the second quantum dots QD2. The first light B reflected by the blue light reflective unit RFL2 may be converted into second light G by the second quantum dots QD2.

In such an embodiment, the first light B that is not converted into second light G by the second quantum dots QD2 may be reflected by the blue light reflective unit RFL2. The reflected first light B may be incident on the second quantum dots QD2 and converted into second light G. Through this process, the efficiency of converting first light B into second light G may be improved.

The green light reflective unit RFL3 may overlap the blue light filter unit CFT3 and may be configured to reflect the second light G. The green light reflective unit RFL3 may improve the efficiency of converting the second light G into third light R.

Referring to FIG. 3B, the first light-emitting layer LEL1 and the second light-emitting layer LEL2 may emit first light B and second light G, respectively. The second light G emitted from the second light-emitting layer LEL2 may be reflected by the green light reflective unit RFL3. A portion of the second light G reflected by the green light reflective unit RFL3 may be scattered by the plurality of third scattering materials SC3 and incident on either the first color conversion unit CCV1 or the second color conversion unit CCV2. Through this process, the efficiency of converting second light G into third light R may be improved.

In such an embodiment, as described above, the optical anisotropic film layer CLC may reflect at least a portion of the light that passes through the quantum dot layer QDL without passing through the quantum dots QD1, QD2. The light reflected by the optical anisotropic film layer CLC may then be re-incident on the quantum dots QD1, QD2 in the quantum dot layer QDL. Therefore, in such an embodiment, the color conversion efficiency can be improved.

A plurality of liquid crystal molecules may be arranged in a helical structure. In the present specification, a helical structure refers to a structure in which the plurality of liquid crystal molecules are arranged in a spiral formation. In addition, in the present specification, the term “selective reflection characteristic” refers to a property whereby the plurality of liquid crystal molecules selectively reflect light of specific wavelengths. The wavelength of the light reflected by the plurality of liquid crystal molecules may be adjusted by the average refractive index of the liquid crystal molecules and the pitch of the helical structure. The pitch refers to the physical distance over which the arrangement of the liquid crystal molecules completes a 360-degree rotation in the aforementioned helical structure.

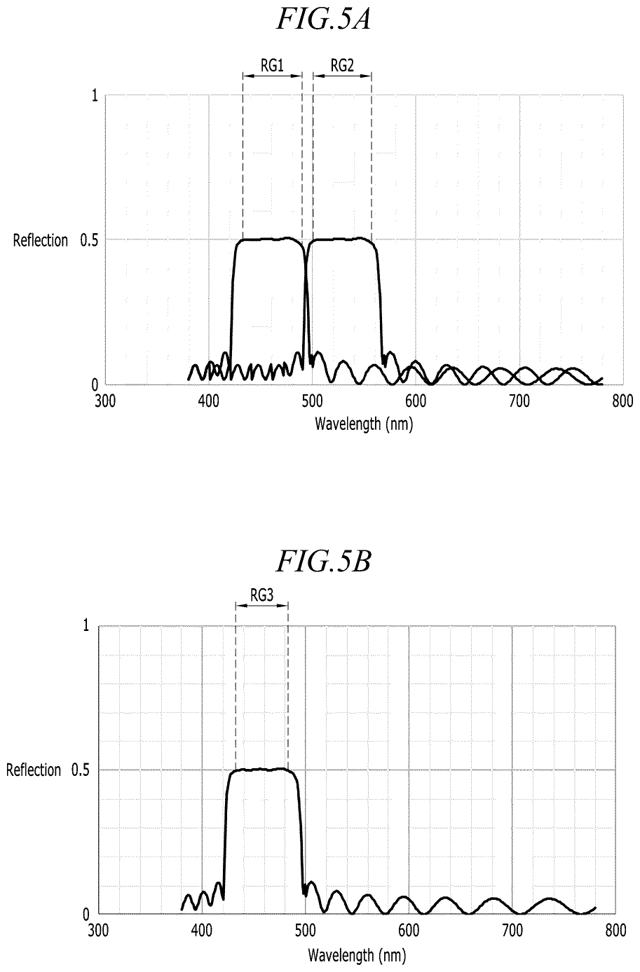

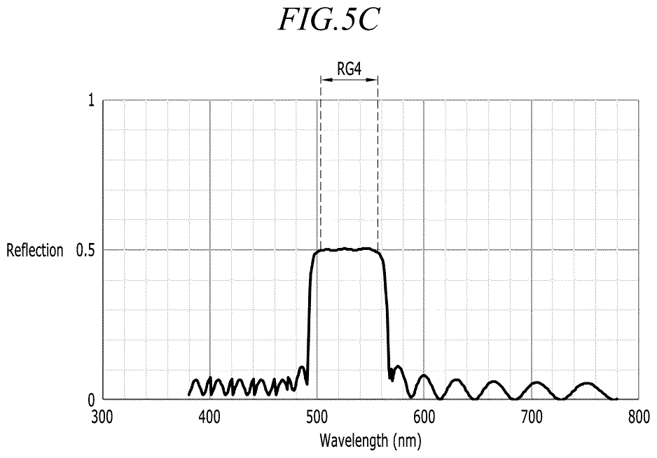

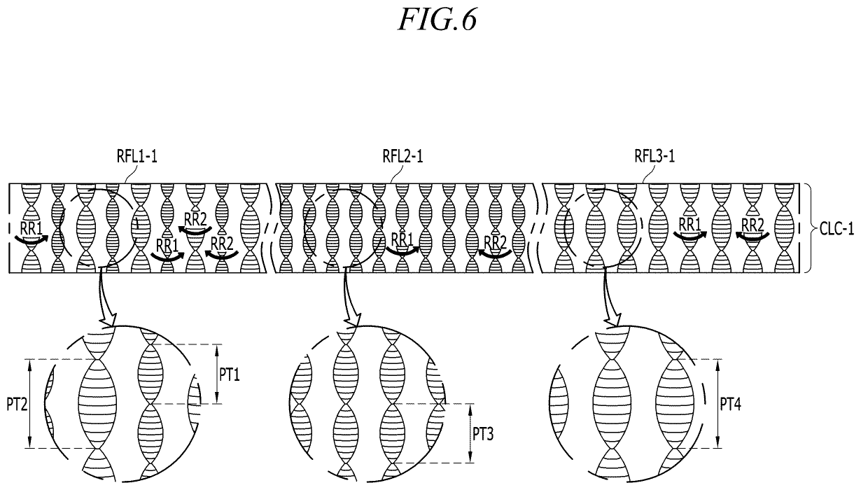

FIG. 4 schematically illustrates the helical structure of a plurality of liquid crystal molecules and pitches PT1, PT2, PT3, PT4 of the helical structures in the optical anisotropic film layer CLC shown in FIG. 3A. FIGS. 5A to 5C illustrate the selective reflection characteristics of the blue-green light reflective unit RFL1, the blue light reflective unit RFL2, and the green light reflective unit RFL3 shown in FIG. 3A.

The blue-green light reflective unit RFL1 may include a plurality of first liquid crystal molecules and a plurality of second liquid crystal molecules. The blue light reflective unit RFL2 may include a plurality of third liquid crystal molecules, and the green light reflective unit RFL3 may include a plurality of fourth liquid crystal molecules.

Hereinafter, the selective reflection characteristics of the blue-green light reflective unit RFL1 will be described with reference to FIGS. 4 and 5A.

The plurality of first liquid crystal molecules may be arranged in a helical structure having a first pitch PT1, and the plurality of second liquid crystal molecules may be arranged in a helical structure having a second pitch PT2. The second pitch PT2 may be different from the first pitch PT1. That is, a first light wavelength range RG1 primarily reflected by the plurality of first liquid crystal molecules may be different from a second light wavelength range RG2 primarily reflected by the plurality of second liquid crystal molecules.

In an embodiment, for example, the first pitch PT1 may be shorter than the second pitch PT2, and the wavelength of light reflected by the plurality of first liquid crystal molecules may be shorter than the wavelength of light reflected by the plurality of second liquid crystal molecules. In such an embodiment, the blue-green light reflective unit RFL1 may have selective reflection characteristics for the first light B and the second light G.

The selective reflection characteristics of the blue light reflective unit RFL2 will now be described with reference to FIGS. 4 and 5B.

The plurality of third liquid crystal molecules may be arranged in a helical structure having a third pitch PT3 that is substantially equal to the first pitch PT1. A third light wavelength range RG3, which is primarily reflected by the plurality of third liquid crystal molecules, may be substantially equal to the first light wavelength range RG1, which is primarily reflected by the plurality of first liquid crystal molecules. That is, the blue light reflective unit RFL2 may have selective reflection characteristics for the first light B.

In an embodiment, for example, the third pitch PT3 may be greater than or equal to 0.9 times the first pitch PT1 and smaller than or equal to 1.1 times the first pitch PT1. However, the third pitch PT3 is not limited thereto and may be variously modified as desired.

Now, the selective reflection characteristics of the green light reflective unit RFL3 will be described with reference to FIGS. 4 and 5C.

The plurality of fourth liquid crystal molecules may be arranged in a helical structure having a fourth pitch PT4 that is substantially equal to the second pitch PT2. A fourth light wavelength range RG4, which is primarily reflected by the plurality of fourth liquid crystal molecules, may be substantially equal to the second light wavelength range RG2, which is primarily reflected by the plurality of second liquid crystal molecules. That is, the green light reflective unit RFL3 may have selective reflection characteristics for the second light G.

In an embodiment, for example, the fourth pitch PT4 may be greater than or equal to 0.9 times the second pitch PT2 and smaller than or equal to 1.1 times the second pitch PT2. However, the fourth pitch PT4 is not limited thereto and may be variously modified as desired.

Each of the first liquid crystal molecule, second liquid crystal molecule, third liquid crystal molecule, and fourth liquid crystal molecule may be, for example, one selected from cholesteryl oleyl carbonate, cholesteryl chloride, cholesteryl nonanoate, polysiloxane-based liquid crystal, polymer network liquid crystal, biphenyl derivatives, cyanobiphenyl, and RM257.

In an embodiment of the disclosure, at least one selected from the average refractive index and the pitch described above may be adjusted based on the type and concentration per unit volume of the liquid crystal molecules. Accordingly, the wavelength of light reflected by the plurality of liquid crystal molecules may also be adjusted.

In an embodiment of the disclosure, any two among a first liquid crystal molecule from the plurality of first liquid crystal molecules, a second liquid crystal molecule from the plurality of second liquid crystal molecules, a third liquid crystal molecule from the plurality of third liquid crystal molecules, and a fourth liquid crystal molecule from the plurality of fourth liquid crystal molecules may be different from each other. In an embodiment, for example, the first liquid crystal molecule may be cholesteryl oleyl carbonate, and each of the second, third, and fourth liquid crystal molecules may be cholesteryl chloride. However, this is merely an example, and the first through fourth liquid crystal molecules are not limited thereto and may be freely selected.

In an embodiment, any two among the concentration per unit volume of the plurality of first liquid crystal molecules, the concentration per unit volume of the plurality of second liquid crystal molecules, the concentration per unit volume of the plurality of third liquid crystal molecules, and the concentration per unit volume of the plurality of fourth liquid crystal molecules may be different from each other. In an embodiment, for example, the concentration per unit volume of the plurality of first liquid crystal molecules may be higher than that of the plurality of second liquid crystal molecules. However, the present disclosure is not limited thereto, and each concentration per unit volume may be variously adjusted.

A chiral dopant may be a material that adjusts the pitch and direction of the helical structure of the liquid crystal molecules in the cholesteric liquid crystal. In an embodiment of the disclosure, at least one selected from the blue-green light reflective unit RFL1, the blue light reflective unit RFL2, and the green light reflective unit RFL3 may further include a plurality of chiral dopants. In an embodiment, for example, the chiral dopant may be one selected from TPE-chol (tetraphenylethylene-cholesterol), QM12, S811, R-811, S5011, R5011, L-glutamine, menthol, photo-responsive chiral molecules, and conductive dopants. However, the chiral dopant is not limited thereto and may be any substance capable of adjusting the pitch and direction of the helical structure of the liquid crystal molecules.

In the present disclosure, “reflectance” refers to the ratio at which any one of the blue-green light reflective unit RFL1-1, the blue light reflective unit RFL2-1, and the green light reflective unit RFL3 reflects incident light. The reflectance may vary depending on the wavelength of the incident light.

As described with reference to FIG. 3B, the blue-green light reflective unit RFL1-1, the blue light reflective unit RFL2-1, and the green light reflective unit RFL3 may reflect at least a portion of light that has passed through the quantum dot layer QDL without passing through the quantum dots QD1, QD2, and redirect the portion of light back toward the quantum dots QD1, QD2. Accordingly, color conversion efficiency may be improved.

Therefore, as the reflectance of the blue-green light reflective unit RFL1, the blue light reflective unit RFL2, and the green light reflective unit RFL3 increases, the color conversion efficiency can be further enhanced.

Hereinafter, with reference to FIG. 6, the technical features of the present disclosure will be described with respect to improving the color conversion efficiency by increasing the reflectance of each of the blue-green light reflective unit RFL1, the blue light reflective unit RFL2, and the green light reflective unit RFL3.

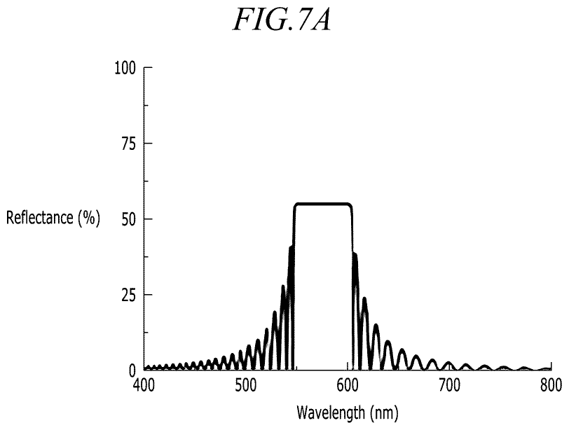

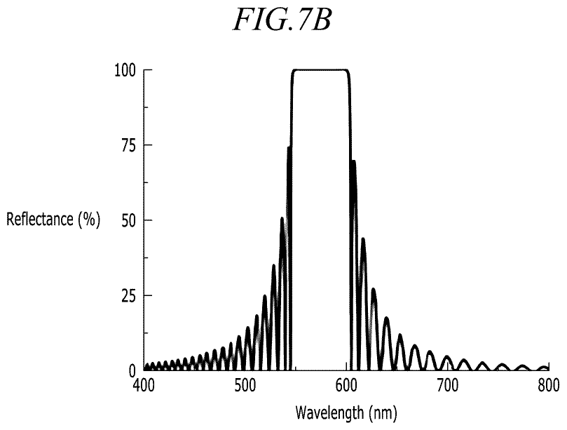

FIG. 6 additionally illustrates the rotational directions DR1, DR2 of the helical structure shown in FIG. 4. FIGS. 7A and 7B are graphs illustrating the relationship between the rotational directions DR1, DR2 of the helical structure and the reflectance of the blue light reflective unit RFL2-1.

The plurality of liquid crystal molecules may be arranged in a helical structure, and the direction of the helical structure may be a first rotational direction RR1 or a second rotational direction RR2. The second rotational direction RR2 may be different from the first rotational direction RR1. In an embodiment, for example, the first rotational direction RR1 may be a direction in which the helical structure twists to the right, and the second rotational direction RR2 may be a direction in which the helical structure twists to the left.

The plurality of liquid crystal molecules may reflect circularly polarized light components that match the rotational direction of the helical structure and transmit circularly polarized light components that are in the opposite direction. In an embodiment, where the direction of the helical structure of the plurality of liquid crystal molecules is the first rotational direction RR1, circularly polarized light in the first rotational direction RR1 may be reflected, while circularly polarized light in the second rotational direction RR2 may be transmitted. In an embodiment, where the helical structure of the plurality of liquid crystal molecules has the second rotational direction RR2, circularly polarized light in the first rotational direction RR1 may be transmitted, and circularly polarized light in the second rotational direction RR2 may be reflected.

Referring to FIG. 6, in an embodiment, each of the blue-green light reflective unit RFL1-1, the blue light reflective unit RFL2-1, and the green light reflective unit RFL3-1 may include both liquid crystal molecules having a helical structure in the first rotational direction RR1 and liquid crystal molecules having a helical structure in the second rotational direction RR2. Therefore, each of the blue-green light reflective unit RFL1-1, the blue light reflective unit RFL2-1, and the green light reflective unit RFL3-1 may be configured to reflect both circularly polarized light components in the first rotational direction RR1 and circularly polarized light components in the second rotational direction RR2.

Accordingly, the reflectance of the blue-green light reflective unit RFL1-1, the reflectance of the blue light reflective unit RFL2-1, and the reflectance of the green light reflective unit RFL3-1 may be higher than the reflectance of the blue-green light reflective unit RFL1, the reflectance of the blue light reflective unit RFL2-1, and the reflectance of the green light reflective unit RFL3 shown in FIG. 4, respectively.

In the blue-green light reflective unit RFL1-1, a portion of the plurality of first liquid crystal molecules may be arranged in a helical structure having the first pitch PT1 and the first rotational direction RR1 and thus may be configured to reflect the circularly polarized component of the first light B in the first rotational direction RR1. The remaining first liquid crystal molecules may be arranged in a helical structure having the first pitch PT1 and the second rotational direction RR2 and thus may be configured to reflect the circularly polarized component of the first light B in the second rotational direction RR2.

In the blue-green light reflective unit RFL1-1, a portion of the plurality of second liquid crystal molecules may be arranged in a helical structure having the second pitch PT2 and the first rotational direction RR1 and thus may be configured to reflect the circularly polarized component of the second light G in the first rotational direction RR1. The remaining second liquid crystal molecules may be arranged in a helical structure having the second pitch PT2 and the second rotational direction RR2 and thus may be configured to reflect the circularly polarized component of the second light G in the second rotational direction RR2.

In the blue light reflective unit RFL2-1, a portion of the plurality of third liquid crystal molecules may be arranged in a helical structure having the third pitch PT3 and the first rotational direction RR1 and thus may be configured to reflect the circularly polarized component of the first light B in the first rotational direction RR1. The remaining third liquid crystal molecules may be arranged in a helical structure having the third pitch PT3 and the second rotational direction RR2 and thus may be configured to reflect the circularly polarized component of the first light B in the second rotational direction RR2.

In the green light reflective unit RFL3-1, a portion of the plurality of fourth liquid crystal molecules may be arranged in a helical structure having the fourth pitch PT4 and the first rotational direction RR1 and thus may be configured to reflect the circularly polarized component of the second light G in the first rotational direction RR1. The remaining fourth liquid crystal molecules may be arranged in a helical structure having the fourth pitch PT4 and the second rotational direction RR2 and thus may be configured to reflect the circularly polarized component of the second light G in the second rotational direction RR2.

Referring to FIGS. 6 and 7A, in an embodiment where the helical structure of all of the plurality of second liquid crystal molecules in the blue light reflective unit RFL2 has either the first rotational direction RR1 or the second rotational direction RR2, the reflectance of the blue light reflective unit RFL2 may be approximately 50%.

Referring to FIGS. 6 and 7B, in an embodiment where some (e.g., a first group) of the plurality of second liquid crystal molecules in the blue light reflective unit RFL2-1 has a helical structure in the first rotational direction RR1 and the remainder thereof has a helical structure in the second rotational direction RR2, the reflectance of the blue light reflective unit RFL2-1 may be approximately 100%.

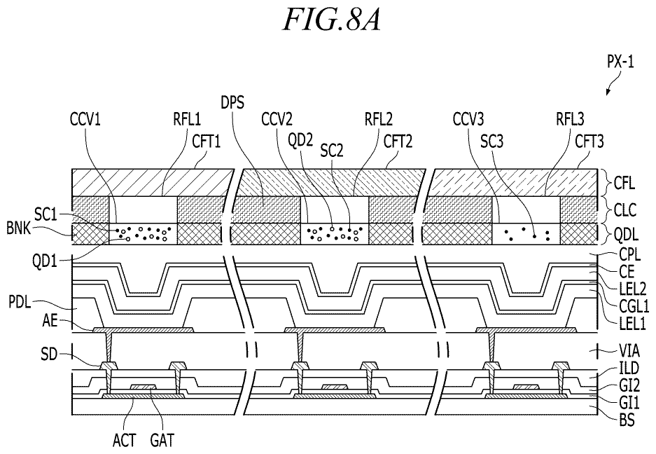

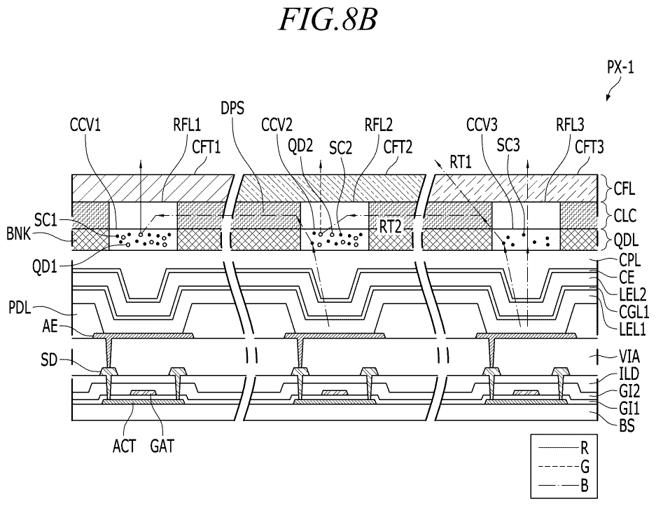

FIG. 8A is a partial cross-sectional view illustrating a pixel PX-1 according to another embodiment of the present disclosure. FIG. 8B illustrates emission of first light B, second light G, and third light R from the pixel PX-1 shown in FIG. 8A. Referring to FIG. 8A, an optical anisotropic film layer CLC-2 of the pixel PX-1 may further include a scattering unit DPS.

The scattering unit DPS may include a plurality of fifth liquid crystal molecules and may be configured to scatter incident light. The scattering unit DPS may be disposed between two adjacent units of the blue-green light reflective unit RFL1, the blue light reflective unit RFL2, and the green light reflective unit RFL3 and may be provided in plural. In an embodiment, for example, a plurality of scattering units DPS may be disposed between the blue-green light reflective unit RFL1 and the blue light reflective unit RFL2, between the blue-green light reflective unit RFL1 and the green light reflective unit RFL3, or between the blue light reflective unit RFL2 and the green light reflective unit RFL3. However, the arrangement of the plurality of scattering units DPS is not limited thereto and may be variously modified as desired.

Referring to FIG. 8A, the first light B emitted from the first light-emitting layer LEL1 may be scattered by the third scattering material SC3 of the third color conversion unit CCV3.

In a case where the scattering unit DPS is not provided, the first light B scattered by the third scattering material SC3 may propagate along a first path RT1 and may mix with the third light R transmitted through the red light filter unit CFT1 or the second light G transmitted through the green light filter unit CFT2. As a result, color mixing may occur, leading to degradation of the display quality of the display panel DP.

In an embodiment where the scattering unit DPS is provided, the first light B scattered by the third scattering material SC3 may be scattered again by the scattering unit DPS. The first light B described above may then propagate along a second path RT2 and may be converted into the second light G or the third light R by the first quantum dots QD1 or the second quantum dots QD2. Accordingly, color mixing can be prevented, thereby improving the display quality of the display panel DP, and the color conversion efficiency may also be enhanced.

The helical structures of the plurality of liquid crystal molecules may be classified as planar state, homeotropic state, or focal conic state depending on the arrangement of the helical axes.

A helical structure in the planar state refers to a structure in which the helical axis is arranged perpendicular to the substrate, while a helical structure in the homeotropic state refers to a structure in which the helical axis is arranged parallel to the substrate. Liquid crystal molecules arranged in a helical structure in either the planar state or the homeotropic state may exhibit selective reflection characteristics.

A helical structure in the focal conic state refers to a structure in which the helical axis is irregularly arranged and exhibits a characteristic of scattering incident light. Liquid crystal molecules arranged in a helical structure in the focal conic state may be configured to scatter incident light.

In an embodiment, each of the plurality of first liquid crystal molecules, second liquid crystal molecules, third liquid crystal molecules, and fourth liquid crystal molecules may be arranged in a helical structure in the planar state or the homeotropic state. In contrast, the plurality of fifth liquid crystal molecules may be arranged in a helical structure in the focal conic state. Accordingly, the scattering unit DPS may be configured to scatter incident light.

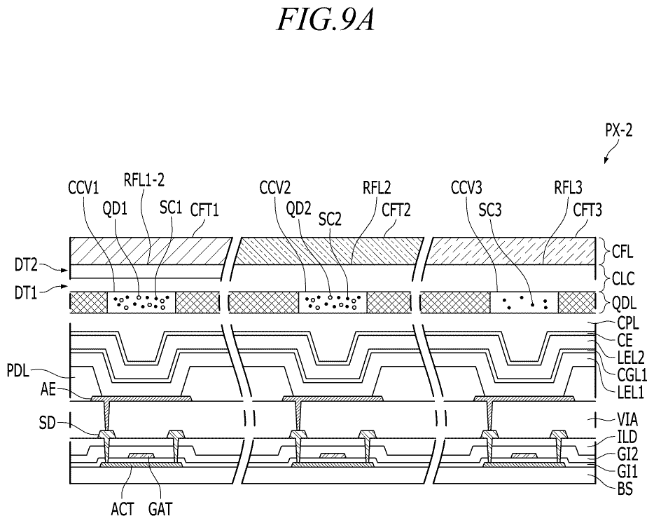

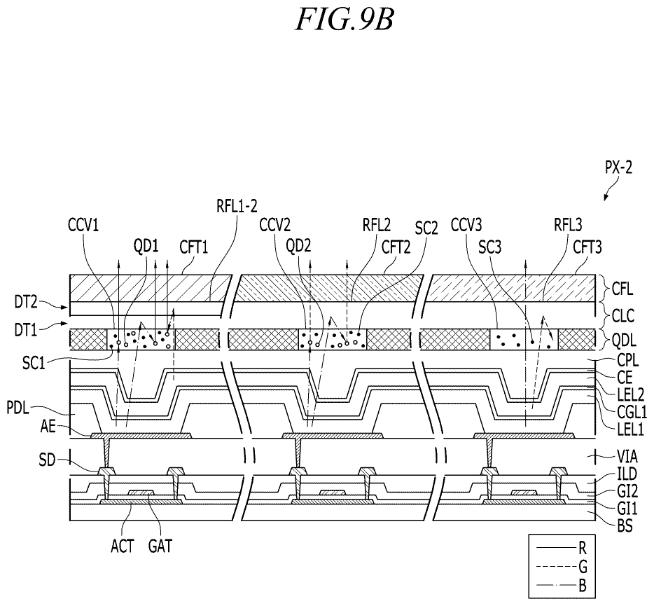

FIG. 9A illustrates a partial cross-sectional view of a pixel PX-2 according to another embodiment of the present disclosure. FIG. 9B illustrates emission of first light B, second light G, and third light R from the pixel PX-2 shown in FIG. 9A.

Referring to FIG. 9A, in another embodiment, the blue-green light reflective unit RFL1-2 may have a first region DT1 and a second region DT2 defined therein.

Referring to FIG. 9B, the first light B may be reflected in the first region DT1, and the second light G may be reflected in the second region DT2. The first region DT1 may be disposed above or below the second region DT2. In other words, the first region DT1 and the second region DT2 may be arranged to overlap each other.

Although FIG. 9B illustrates an embodiment where the first region DT1 is disposed below the second region DT2, this is merely an example, and the arrangement of the first region DT1 and the second region DT2 is not limited thereto. In another embodiment, for example, the first region DT1 may be disposed above the second region DT2.

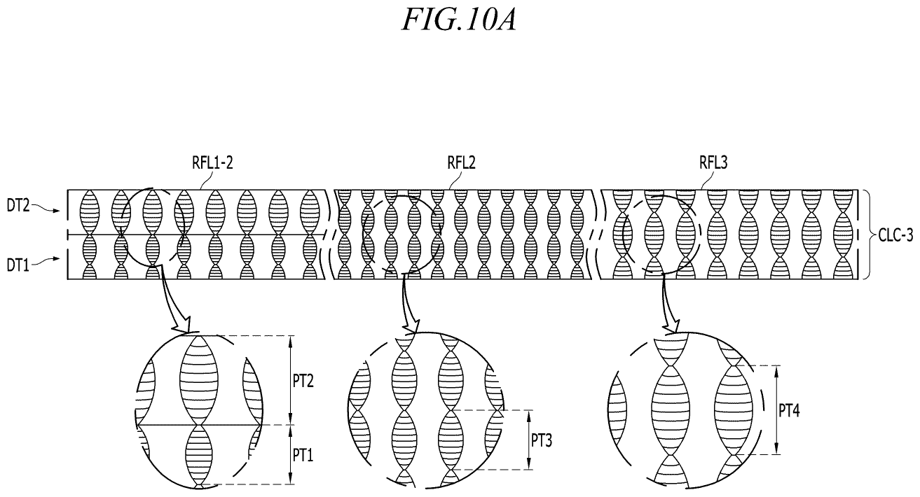

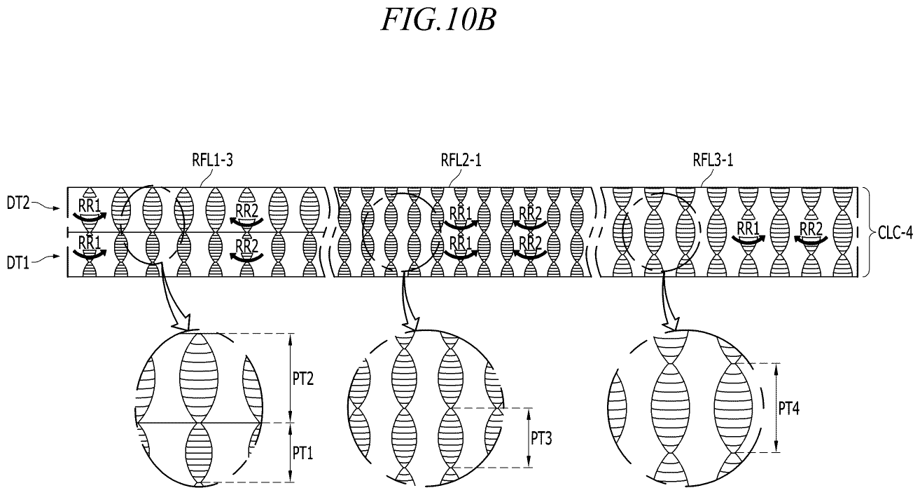

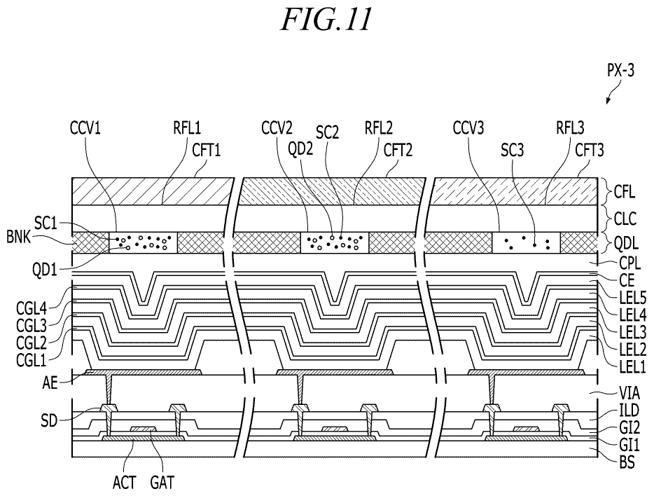

FIG. 10A illustrates the helical structure of a plurality of liquid crystal molecules and the pitches PT1, PT2, PT3, PT4 of the helical structures in an optical anisotropic film layer CLC-3 shown in FIG. 9A. FIG. 10B additionally illustrates the rotational directions DR1, DR2 of the helical structure shown in FIG. 10A.

Referring to FIG. 10A, in an embodiment, the plurality of first liquid crystal molecules may be disposed in the first region DT1, and the plurality of second liquid crystal molecules may be disposed in the second region DT2. The plurality of first liquid crystal molecules may be disposed above or below the plurality of second liquid crystal molecules.

Referring to FIG. 10B, each of the blue-green light reflective unit RFL1-3, the blue light reflective unit RFL2-1, and the green light reflective unit RFL3-1 may include both liquid crystal molecules having a helical structure in the first rotational direction RR1 and liquid crystal molecules having a helical structure in the second rotational direction RR2. Therefore, each of the blue-green light reflective unit RFL1-3, the blue light reflective unit RFL2-1, and the green light reflective unit RFL3-1 may be configured to reflect both the circularly polarized component in the first rotational direction RR1 and the circularly polarized component in the second rotational direction RR2.

FIG. 11 illustrates a partial cross-sectional view of a pixel PX-3 according to another embodiment of the present disclosure. Referring to FIG. 11, in another embodiment, the pixel PX-3 may further include a second charge generation layer CGL2, a third light-emitting layer LEL3, a third charge generation layer CGL3, a fourth light-emitting layer LEL4, a fourth charge generation layer CGL4, and a fifth light-emitting layer LEL5.

Each of the third light-emitting layer LEL3, the fourth light-emitting layer LEL4, and the fifth light-emitting layer LEL5 may be configured to emit either the first light B or the second light G. In an embodiment, for example, each of the first light-emitting layer LEL1, the second light-emitting layer LEL2, and the fourth light-emitting layer LEL4 may be configured to emit the first light B, and each of the third light-emitting layer LEL3 and the fifth light-emitting layer LEL5 may be configured to emit the second light G.

The third light-emitting layer LEL3 may be disposed between the second charge generation layer CGL2 and the third charge generation layer CGL3. The fourth light-emitting layer LEL4 may be disposed between the third charge generation layer CGL3 and the fourth charge generation layer CGL4. The fifth light-emitting layer LEL5 may be disposed between the fourth charge generation layer CGL4 and the cathode electrode CE.

Each of the second charge generation layer CGL2, the third charge generation layer CGL3, and the fourth charge generation layer CGL4 may include a conductive material. The second charge generation layer CGL2 may be disposed between the second light-emitting layer LEL2 and the third light-emitting layer LEL3 and may cover the second light-emitting layer LEL2. The third charge generation layer CGL3 may be disposed between the third light-emitting layer LEL3 and the fourth light-emitting layer LEL4 and may cover the third light-emitting layer LEL3. The fourth charge generation layer CGL4 may be disposed between the fourth light-emitting layer LEL4 and the fifth light-emitting layer LEL5 and may cover the fourth light-emitting layer LEL4.

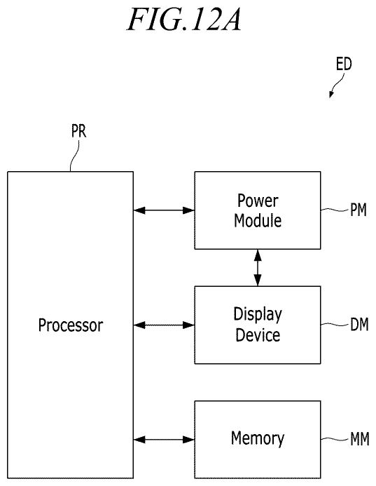

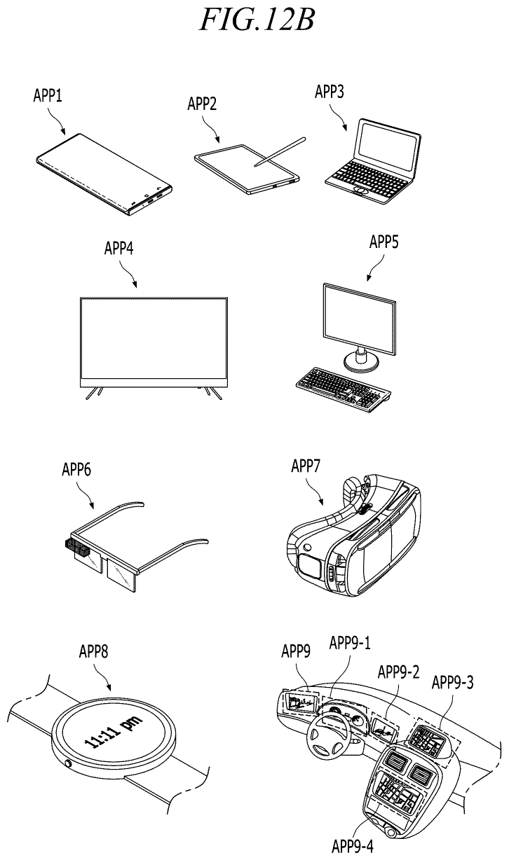

FIG. 12A is a block diagram illustrating the electronic device ED shown in FIG. 1A. FIG. 12B illustrates various embodiments of the electronic device ED. Referring to FIGS. 12A and 12B, the electronic device ED may include a display panel DP, a processor PR, a memory MM, and a power module PM.

The processor PR may include at least one selected from a central processing unit (CPU), an application processor (AP), a graphic processing unit (GPU), a communication processor (CP), an image signal processor (ISP), and a controller.

The memory MM may have stored therein data information (or instructions) used for operating at least one selected from the processor PR and the display panel DP.

The processor PR may be configured to control the display panel DP. When the processor PR executes an application stored in the memory MM, image data signals and/or input control signals may be transferred to the display panel DP, which then may process the received signals to output an image.

The power module PM may be configured to generate or supply power. The power module PM may include a power supply module, such as a power adapter or a battery device, and a power conversion module configured to convert the power supplied by the power supply module into power required for operating the electronic device ED.

In an embodiment of the disclosure, the display panel DP may include at least one selected from the processor PR, the memory MM, and the power module PM. In an embodiment, for example, some (e.g., at least two) of the individual modules included functionally within a single module may be included in the display panel DP while others may be provided separately from the display panel DP.

In another embodiment of the disclosure, the electronic device ED may include the display panel DP, and the processor PR, memory MM, and power module PM may be provided separately from the display panel DP.

In an embodiment, the electronic device ED may be a smartphone, but the electronic device ED of the present disclosure is not limited thereto. The electronic device ED may include large-sized display devices and medium-or small-sized display devices. In an embodiment, for example, large-sized display devices may include televisions, monitors, and electronic signboards, and medium-or small-sized display devices may include tablets, built-in displays in home appliances, smartwatches, and smartphones.

Referring to FIG. 12B, the electronic device ED including the display panel DP according to embodiments of the disclosure may include not only image display devices, such as a smartphone APP1, a tablet personal computer (PC) APP2, a laptop computer APP3, a television (TV) APP4, and a desktop monitor APP5, but also wearable electronic devices including the display panel DP, such as smart glasses APP6, a head-mounted display APP7, and a smartwatch APP8, as well as automotive electronic devices APP9 to APP9-4 including the display panel, such as an instrument panel, a center fascia, a dashboard-mounted center information display (CID), or a room mirror display.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display panel comprising:
a first light-emitting layer which emit first light having a first wavelength;
a second light-emitting layer overlapping the first light-emitting layer, wherein the second light-emitting layer emits second light having a second wavelength longer than the first wavelength;
a quantum dot layer comprising a first color conversion unit and a second color conversion unit, wherein the first color conversion unit converts at least part of the first light and the second light into third light, the second color conversion unit converts at least part of the first light into the second light, and the third light has a third wavelength longer than the second wavelength;
a color filter layer comprising:
a red light filter unit overlapping the first color conversion unit, a green light filter unit overlapping the second color conversion unit, and a blue light filter unit disposed not to overlap the first color conversion unit and the second color conversion unit, wherein the red light filter unit allows the third light to transmit therethrough, the green light filter unit allows the second light to transmit therethrough, the blue light filter unit allows the first light to transmit therethrough; and
an optical anisotropic film layer disposed between the quantum dot layer and the color filter layer, wherein the optical anisotropic film layer comprises a blue-green light reflective unit overlapping the red light filter unit, a blue light reflective unit overlapping the green light filter unit, and a green light reflective unit overlapping the blue light filter unit, wherein the blue-green light reflective unit reflects the second light and the third light, the blue light reflective unit reflects the first light, the green light reflective unit reflects the second light.

2. The display panel of claim 1, wherein the blue-green light reflective unit comprises:
a plurality of first liquid crystal molecules arranged in a helical structure having a first pitch; and
a plurality of second liquid crystal molecules arranged in a helical structure having a second pitch different from the first pitch,
wherein the blue light reflective unit comprises a plurality of third liquid crystal molecules arranged in a helical structure having a third pitch substantially equal to the first pitch, and
wherein the green light reflective unit comprises a plurality of fourth liquid crystal molecules arranged in a helical structure having a fourth pitch substantially equal to the second pitch.

3. The display panel of claim 2, wherein two among a first liquid crystal molecule from the plurality of first liquid crystal molecules, a second liquid crystal molecule from the plurality of second liquid crystal molecules, a third liquid crystal molecule from the plurality of third liquid crystal molecules, and a fourth liquid crystal molecule from the plurality of fourth liquid crystal molecules are different from each other.

4. The display panel of claim 2, wherein two among a concentration per unit volume of the plurality of first liquid crystal molecules, a concentration per unit volume of the plurality of second liquid crystal molecules, a concentration per unit volume of the plurality of third liquid crystal molecules, and a concentration per unit volume of the plurality of fourth liquid crystal molecules are different from each other.

5. The display panel of claim 2, wherein at least one selected from the blue-green light reflective unit, the blue light reflective unit, and the green light reflective unit further comprises a plurality of chiral dopants.

6. The display panel of claim 2, wherein some of the plurality of first liquid crystal molecules are arranged in helical structures having a first rotational direction, and a remainder of the plurality of first liquid crystal molecules are arranged in helical structures having a second rotational direction,
wherein some of the plurality of second liquid crystal molecules are arranged in helical structures having the first rotational direction, and a remainder of the plurality of second liquid crystal molecules are arranged in helical structures having the second rotational direction,
wherein some of the plurality of third liquid crystal molecules are arranged in helical structures having the first rotational direction, and a remainder of the plurality of third liquid crystal molecules are arranged in helical structures having the second rotational direction,
wherein some of the plurality of fourth liquid crystal molecules are arranged in helical structures having the first rotational direction, and a remainder of the plurality of fourth liquid crystal molecules are arranged in helical structures having the second rotational direction, and
wherein the first rotational direction is different from the second rotational direction.

7. The display panel of claim 2, wherein the optical anisotropic film layer further comprises a scattering unit which scatters incident light.

8. The display panel of claim 7, wherein the scattering unit is disposed between adjacent two units of the blue-green light reflective unit, the blue light reflective unit, and the green light reflective unit.

9. The display panel of claim 8, wherein the scattering unit comprises a plurality of fifth liquid crystal molecules,
wherein each of the plurality of first liquid crystal molecules, the plurality of second liquid crystal molecules, the plurality of third liquid crystal molecules, and the plurality of fourth liquid crystal molecules is arranged in a helical structure in a planar state or in a helical structure in a homeotropic state, and
wherein the plurality of fifth liquid crystal molecules is arranged in a helical structure in a focal conic state.

10. The display panel of claim 2, wherein the plurality of first liquid crystal molecules is disposed above or below the plurality of second liquid crystal molecules.

11. A display panel comprising:
a first light-emitting layer which emits first light having a first wavelength;
a second light-emitting layer overlapping the first light-emitting layer, wherein the second light-emitting layer emits second light having a second wavelength longer than the first wavelength;
a quantum dot layer comprising a first color conversion unit and a second color conversion unit, wherein the first color conversion unit converts at least part of the first light and the second light into third light, the second color conversion unit converts at least part of the first light into the second light, and the third light has a third wavelength longer than the second wavelength;
a color filter layer comprising a red light filter unit which allows the third light to transmit therethrough, a green light filter unit which allows the second light to transmit therethrough, and a blue light filter unit which allows the first light to transmit therethrough;
a blue-green light reflective unit comprising a plurality of first liquid crystal molecules and a plurality of second liquid crystal molecules, wherein the plurality of first liquid crystal molecules is arranged in a helical structure having a first pitch between the first color conversion unit and the red light filter unit, and the plurality of second liquid crystal molecules is arranged in a helical structure having a second pitch different from the first pitch between the first color conversion unit and the red light filter unit;
a blue light reflective unit comprising a plurality of third liquid crystal molecules arranged in a helical structure having a third pitch substantially equal to the first pitch between the second color conversion unit and the green light filter unit; and
a green light reflective unit overlapping the blue light filter unit, wherein the green light reflective unit comprises a plurality of fourth liquid crystal molecules arranged in a helical structure having a fourth pitch substantially equal to the second pitch.

12. The display panel of claim 11, wherein two among a first liquid crystal molecule from the plurality of first liquid crystal molecules, a second liquid crystal molecule from the plurality of second liquid crystal molecules, a third liquid crystal molecule from the plurality of third liquid crystal molecules, and a fourth liquid crystal molecule from the plurality of fourth liquid crystal molecules are different from each other.

13. The display panel of claim 11, wherein two among a concentration per unit volume of the plurality of first liquid crystal molecules, a concentration per unit volume of the plurality of second liquid crystal molecules, a concentration per unit volume of the plurality of third liquid crystal molecules, and a concentration per unit volume of the plurality of fourth liquid crystal molecules are different from each other.

14. The display panel of claim 11, wherein at least one selected from the blue-green light reflective unit, the blue light reflective unit, and the green light reflective unit further comprises a plurality of chiral dopants.

15. The display panel of claim 11, wherein some of the plurality of first liquid crystal molecules are arranged in helical structures having a first rotational direction, and a remainder of the plurality of first liquid crystal molecules are arranged in helical structures having a second rotational direction,
wherein some of the plurality of second liquid crystal molecules are arranged in helical structures having the first rotational direction, and a remainder of the plurality of second liquid crystal molecules are arranged in helical structures having the second rotational direction,
wherein some of the plurality of third liquid crystal molecules are arranged in helical structures having the first rotational direction, and a remainder of the plurality of third liquid crystal molecules are arranged in helical structures having the second rotational direction,
wherein some of the plurality of fourth liquid crystal molecules are arranged in helical structures having the first rotational direction, and a remainder of the plurality of fourth liquid crystal molecules are arranged in helical structures having the second rotational direction, and
wherein the first rotational direction and the second rotational direction are different from each other.

16. The display panel of claim 11, further comprising a scattering unit which scatters incident light and is disposed between the quantum dot layer and the color filter layer.

17. The display panel of claim 16, wherein the scattering unit comprises a plurality of fifth liquid crystal molecules,
wherein each of the plurality of first liquid crystal molecules, the plurality of second liquid crystal molecules, the plurality of third liquid crystal molecules, and the plurality of fourth liquid crystal molecules is arranged in a helical structure in a planar state or in a helical structure in a homeotropic state, and
wherein the plurality of fifth liquid crystal molecules is arranged in a helical structure in a focal conic state.

18. The display panel of claim 11, wherein the plurality of first liquid crystal molecules is disposed above or below the plurality of second liquid crystal molecules.

19. An electronic device comprising:
a display panel which emits light;
a processor which controls the display panel;
a memory in which data including instructions for operation of at least one selected from the display panel and the processor is stored; and
a power module which generates power,
wherein the display panel comprises:
a first light-emitting layer which emits first light having a first wavelength;
a second light-emitting layer overlapping the first light-emitting layer, wherein the second light-emitting layer emits second light having a second wavelength longer than the first wavelength;
a quantum dot layer comprising a first color conversion unit and a second color conversion unit, wherein the first color conversion unit converts at least part of the first light and the second light into third light, the second color conversion unit converts at least part of the first light into the second light, and the third light has a third wavelength longer than the second wavelength;
a color filter layer comprising a red light filter unit overlapping the first color conversion unit, a green light filter unit overlapping the second color conversion unit, and a blue light filter unit disposed not to overlap the first color conversion unit and the second color conversion unit, wherein the red light filter unit transmits the third light, the green light filter unit transmits the second light, the blue light filter unit transmits the first light; and
an optical anisotropic film layer disposed between the quantum dot layer and the color filter layer, wherein the optical anisotropic film layer comprises a blue-green light reflective unit overlapping the first color conversion unit, a blue light reflective unit overlapping the second color conversion unit, and a green light reflective unit disposed not to overlap the first color conversion unit and the second color conversion unit, wherein the blue-green light reflective unit reflects the second light and the third light, the blue light reflective unit reflects the first light, and the green light reflective unit reflects the second light.

20. The electronic device according to claim 19, wherein the blue-green light reflective unit comprises:
a plurality of first liquid crystal molecules arranged in a helical structure having a first pitch; and
a plurality of second liquid crystal molecules arranged in a helical structure having a second pitch different from the first pitch,
wherein the blue light reflective unit comprises a plurality of third liquid crystal molecules arranged in a helical structure having a third pitch substantially equal to the first pitch, and
wherein the green light reflective unit comprises a plurality of fourth liquid crystal molecules arranged in a helical structure having a fourth pitch substantially equal to the second pitch.
